(19) United States
(12) Patent Application Publication
(10) Pub. No.: US 2026/0150332 A1
(43) Pub. Date: May 28, 2026

(54) SEMICONDUCTOR DEVICES WITH FIELD PLATE SPACER OVER STI

(71) Applicant: TEXAS INSTRUMENTS INCORPORATED, Dallas, TX (US)

(72) Inventors: Pinghai Hao, Plano, TX (US); Bikram Kishore Mahajan, Richardson, TX (US); Dhanoop Varghese, Plano, TX (US); Srikanth Krishnan, Plano, TX (US)

(21) Appl. No.: 18/962,652

(22) Filed: Nov. 27, 2024

(51) Int. Cl. H10D 30/65; H01L 21/762; H10D 30/01; H10D 30/60

(52) U.S. Cl. CPC H10D 30/65; H10D 30/0285; H10D 30/603; H10W 10/014; H10W 10/17

(57) ABSTRACT

Semiconductor devices and fabrication methods thereof are described. For example, a semiconductor device includes a source region and a drain region having a first conductivity type disposed in a semiconductor layer having an opposite second conductivity type, a shallow trench isolation structure disposed in the semiconductor layer between the source region and the drain region, a gate dielectric layer disposed over the semiconductor layer and extending between the source region and the shallow trench isolation structure, a gate electrode disposed over the gate dielectric layer and extending toward the drain region and over the shallow trench isolation structure, and a field plate spacer between the gate electrode and the shallow trench isolation structure.

### TECHNICAL FIELD

The present disclosure relates to the field of integrated circuits, and more particularly, but not exclusively, to transistors such as laterally diffused metal oxide semiconductor (LDMOS) transistors.

### BACKGROUND

LDMOS devices are field-effect transistors (FETs) that are applicable to high power applications. In an LDMOS device, the drain and source have a relatively large spacing between them, as compared with metal oxide semiconductor (MOS) devices designed for other applications such as logic functions, and lateral diffusions are used to produce a well-controlled drift region from the channel region to the drain. The operational performance of LDMOS devices is generally affected by parameters including, for example, a specific on-resistance (Rsp) and a breakdown voltage (BV). One design goal of LDMOS devices is to decrease Rsp and increase BV, or at least to improve one parameter without adversely affecting the other parameter.

### SUMMARY

The present disclosure describes semiconductor devices with a field plate spacer between a gate electrode and a shallow trench isolation structure and methods of fabrication thereof. This summary is not an extensive overview of the disclosure. Rather, a purpose of the summary is to present some examples of the present disclosure in a simplified form as a prelude to a more detailed description that is presented later.

In some examples, a semiconductor device includes a source region and a drain region having a first conductivity type disposed in a semiconductor layer having an opposite second conductivity type, a shallow trench isolation structure disposed in the semiconductor layer between the source region and the drain region, a gate dielectric layer disposed over the semiconductor layer and extending between the source region and the shallow trench isolation structure, a gate electrode disposed over the gate dielectric layer and extending toward the drain region and over the shallow trench isolation structure, and a field plate spacer between the gate electrode and the shallow trench isolation structure

In some other examples, a method of fabricating a semiconductor device includes forming a source region and a drain region having a first conductivity type in a semiconductor layer having an opposite second conductivity type, forming a shallow trench isolation structure in the semiconductor layer between the source region and the drain region, forming a gate dielectric layer over the semiconductor layer and extending between the source region and the shallow trench isolation structure, forming a gate electrode over the gate dielectric layer and extending toward the drain region and over the shallow trench isolation structure, and forming a field plate spacer between the gate electrode and the shallow trench isolation structure.

### BRIEF DESCRIPTION OF THE DRAWINGS

FIG. 1 is a cross-sectional view of a semiconductor device having a field plate spacer between a gate electrode and a shallow trench isolation structure in accordance with an example of the present disclosure;

FIGS. 2A-2H are cross-sectional views of a method of fabricating a semiconductor device with a field plate spacer between a gate electrode and a shallow trench isolation structure in accordance with an example of the present disclosure;

FIG. 3 is a cross-sectional view of a semiconductor device having a field plate spacer between a gate electrode and a shallow trench isolation structure in accordance with an example of the present disclosure;

FIG. 4 is a cross-sectional view of another semiconductor device having a field plate spacer between a gate electrode and a shallow trench isolation structure in accordance with an example of the present disclosure;

FIG. 5 is a cross-sectional view of another semiconductor device having a field plate spacer between a gate electrode and a shallow trench isolation structure in accordance with an example of the present disclosure;

FIG. 6 is a cross-sectional view of a semiconductor device having a field plate spacer between a gate electrode and a shallow trench isolation structure having a cone defect in accordance with an example of the present disclosure;

FIGS. 7A and 7B are cross-sectional views of electric field profiles of semiconductor devices without and with a field plate spacer between a gate electrode and a shallow trench isolation structure in accordance with an example of the present disclosure;

FIG. 8 shows a plot of electric field as a function of distance from a drain-side edge of a shallow trench isolation structure for semiconductor devices without and with a field plate spacer between a gate electrode and the shallow trench isolation structure in accordance with an example of the present disclosure; and

FIGS. 9A-9G are cross-sectional views of semiconductor devices with field plate spacers between gate electrodes and shallow trench isolation structures, and a table of breakdown voltage, drain-to-source current and on-state resistance of the semiconductor devices, in accordance with an example of the present disclosure.

### DETAILED DESCRIPTION

The present disclosure is described with reference to the attached figures. The components in the figures are not drawn to scale. Instead, emphasis is placed on clearly illustrating overall features and principles of the present disclosure. Numerous specific details and relationships are set forth with reference to examples of the figures to provide an understanding of the present disclosure. The figures and examples are not meant to limit the scope of the present disclosure to such examples, and other examples are possible by way of interchanging or modifying at least some of the described or illustrated elements. Moreover, where elements of the present disclosure can be partially or fully implemented using known components, certain portions of such components that facilitate an understanding of the present disclosure are described, and detailed descriptions of other portions of such components are omitted so as not to obscure the present disclosure.

As used herein, terms such as “first” and “second” are used to arbitrarily distinguish between the elements such terms describe. Thus, these terms in the description and in the claims are not intended to indicate temporal or other prioritization of such elements. Moreover, terms such as “front,” “back,” “top,” “bottom,” “over,” “under,” “vertical,” “horizontal,” “lateral,” “down,” “up,” “upper,” “lower,” or the like, are used to refer to relative directions or positions of features in devices in view of the orientation shown in the figures. For example, “upper” or “uppermost” can refer to a feature positioned closer to the top of a page than other features. The terms so used are interchangeable under appropriate circumstances such that the examples and illustrations of the technology described herein are, for example, capable of operation in other orientations than those illustrated or otherwise described herein. In the following discussion and in the claims, the terms “including,” “includes,” “having,” “has,” “with,” or variants thereof are intended to be inclusive in a manner similar to the term “comprising,” and thus should be interpreted to mean, for example, “including, but not limited to.” Further, in some examples, the terms “about” or “approximately,” preceding a value mean +/−10-20 percent of the stated value. The terms “substantially” or “substantially equal” means values within ±2.5% of the stated value. Still further, unless otherwise specified, the ordering of steps in the description and in the claims are not intended to limit sequencing of the performance of steps and thus alternate step sequencing is contemplated as appropriate.

Various structures disclosed herein can be formed using semiconductor process techniques. Layers including a variety of materials can be formed over a substrate (e.g., a semiconductor wafer), for example, using deposition techniques (e.g., chemical vapor deposition, physical vapor deposition, atomic layer deposition, spin coating, plating), thermal process techniques (e.g., oxidation, nitridation, epitaxy), and/or other suitable techniques. Similarly, some portions of the layers can be selectively removed, for example, using etching techniques (e.g., plasma (or dry) etching, wet etching), chemical mechanical planarization, and/or other suitable techniques, some of which may be combined with photolithography steps. The conductivity (or resistivity) of the substrate (or regions of the substrate) can be controlled by doping techniques using various chemical species (which may also be referred to as dopants, dopant atoms, or the like) including, but not limited to, boron, gallium, indium, arsenic, phosphorus, or antimony. Doping may be performed during the initial formation or growth of the substrate (or an epitaxial layer grown on the substrate), by ion-implantation, or other suitable doping techniques.

As mentioned, the operational performance of an LDMOS device is generally affected by a tradeoff between a specific on-resistance (Rsp) or a drain-source on-resistance (Rdson) parameter and a breakdown voltage (BV) parameter. For example, design approaches that seek to achieve the advantage of a higher BV by increasing the body area of the device consequently lead to the disadvantage of a higher Rsp. Similarly, design approaches that seek to decrease Rsp generally come at the cost of decreasing the BV rating. Accordingly, LDMOS design approaches that effectively manage this tradeoff provide technical advantages.

LDMOS or other power devices may be designed for high voltage and/or high current operation, such as in power management applications. Achieving a better Rdson versus BV tradeoff for high voltage components is an important aspect of device performance.

Semiconductor devices, such as drain extended transistor devices, are described herein which allow for improved device performance (e.g., reduced Rdson and/or greater BV) through the introduction of a field plate spacer which is disposed between a shallow trench isolation (STI) structure and a gate electrode. The improved device performance may be a result, for example, of maintaining device size and Rdson with a higher BV, or maintaining a same Rdson and BV while reducing device size resulting in product die size reduction. Illustrative embodiments are also advantageously able to significantly reduce shallow trench isolation (STI) “cone” related reliability risks, including for high voltage devices such as drain extended transistors. Drain extended transistors can include drain-extended NMOS (DENMOS), drain-extended PMOS (DEPMOS), and/or laterally diffused MOS (LDMOS) transistors, as well as groups of DENMOS and DEPMOS, referred to as complimentary drain extended MOS or DECMOS transistors. While examples of the disclosure may be expected to provide improvements such as described, no particular result is a requirement of the present invention unless explicitly recited in a particular claim.

In some examples, a semiconductor device includes a source region and a drain region having a first conductivity type disposed in a semiconductor layer having an opposite second conductivity type, an STI structure disposed in the semiconductor layer between the source region and the drain region, a gate dielectric layer disposed over the semiconductor layer and extending between the source region and the STI structure, a gate electrode disposed over the gate dielectric layer and extending toward the drain region and over the STI structure, and a field plate spacer between the gate electrode and the STI structure. The STI structure may be a first dielectric material, and the field plate spacer may be a different second dielectric material. The first dielectric material may be silicon oxide and the second dielectric material may be silicon nitride. The second dielectric material may have a greater dielectric permittivity than the first dielectric material. In some examples, the gate electrode covers at least 40% of the field plate spacer, more than 50% of the field plate spacer, or at least 90% of the field plate spacer. The source region and the drain region may be components of an LDMOS transistor.

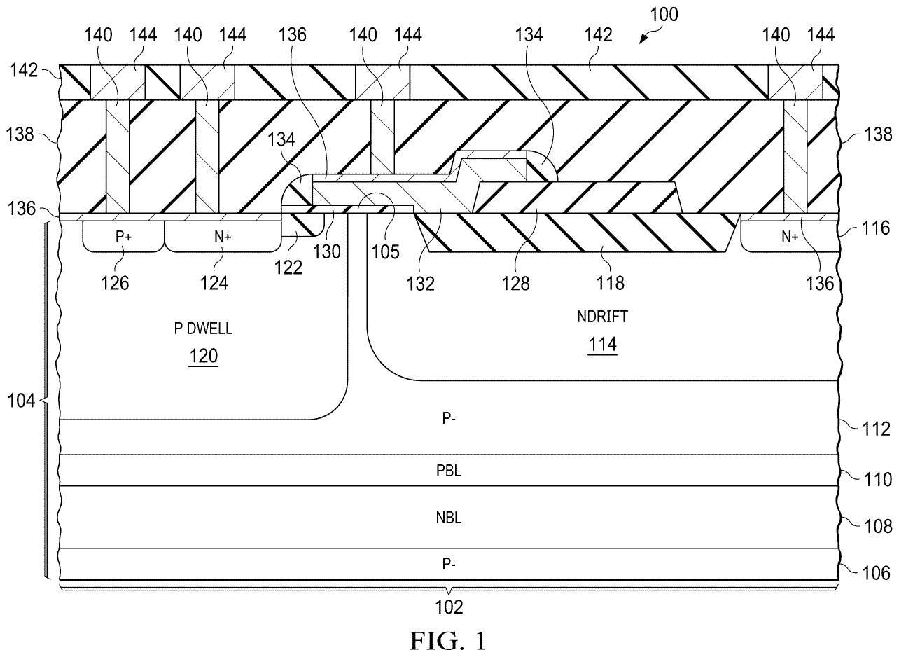

Referring now to FIG. 1, a cross-sectional view of a microelectronic device 100, e.g., an integrated circuit (IC), is shown. The microelectronic device 100 includes an LDMOS transistor 102. FIG. 1 shows an example where the LDMOS transistor 102 is an n-channel device. It should be appreciated, however, that an analogous p-channel device may be formed with appropriate substitution of p-type regions for n-type regions and vice versa. The LDMOS transistor 102 is located in and over an epitaxial layer 104 over a substrate (not explicitly shown). The epitaxial layer 104 may be formed initially as a lightly-doped p-type layer, from which other regions of the LDMOS transistor 102 are formed by additional suitable doping. The semiconductor material of the epitaxial layer 104 is not limited to any particular material, but is described herein as silicon without implied limitation. The LDMOS transistor 102 includes an optional n-type buried layer (NBL) 108 and an optional p-type buried layer (PBL) 110. A “buried layer” is defined as a layer having a first doping characteristic, e.g. conductivity type, dopant type or dopant concentration, spaced apart from a top surface of the epitaxial layer 104 by another layer having a different second doping characteristic. An unmodified portion 106 of the epitaxial layer 104 is located between the NBL 108 and the substrate, and an unmodified portion 112 of the epitaxial layer 104 is located between the PBL 110 and a top surface 105 of the epitaxial layer 104. The unmodified portion 112 of the epitaxial layer 104 may also be referred to herein as lightly doped region 112 or p-epi region 112.

An n-type drift (NDRIFT) region 114 and a p-type DWELL region 120 are formed in the epitaxial layer 104 between the PBL 110 and the top surface 105 of the epitaxial layer 104. The p-type DWELL region 120 may operate as a body region of the LDMOS transistor 102, and the NDRIFT region 114 may operate as an extended drift region of the LDMOS transistor 102. Within the NDRIFT region 114 is a drain region 116 and a shallow trench isolation (STI) structure 118 (also referred to as a field relief dielectric layer 118). Within the p-type DWELL region 120 is an n-type source extension region 122, a source region 124, and a back gate or body contact region 126. The drain region 116 and the source region 124 are n-type, and the back gate or body contact region 126 is p-type. The STI structure 118 fills a field isolation trench formed in the NDRIFT region 114, and may be primarily silicon dioxide (SiO₂) or a SiO₂-based dielectric material formed by one or more chemical-mechanical polishing (CMP) processes alternated with etch-back processes to provide complete filling of the field isolation trench. As shown in FIG. 1, the STI structure 118 is planarized so that it does not extend over the top surface 105 of the epitaxial layer 104. A field plate spacer 128 is formed over at least a portion of the STI structure 118, as will be discussed in further detail below. The electric field at the interface between the STI structure 118 and the underlying epitaxial layer 104 is a function of a lateral position of the field plate spacer 128. The field plate spacer 128 may be a dielectric material that is different than the STI structure 118, and may further have a dielectric constant k greater than that of the STI structure 118. For example, the STI structure 118 may predominantly comprise silicon oxide with a k≈3.9, and the field plate spacer 128 may predominantly comprise a nitride material, such as silicon nitride (SiN) with k≈8-10, silicon oxynitride (SiON with k≈4-7), etc.

A channel region including the p-type DWELL region 120 and the p-epi region 112 is located between the n-type source extension region 122 and the NDRIFT region 114. A gate dielectric layer 130 is located over the channel region, and extends from the n-type source extension region 122 to the STI structure 118. A gate electrode 132 extends from the n-type source extension region 122 toward the drain region 116 over the gate dielectric layer 130 and over the STI structure 118 and the field plate spacer 128 formed over the STI structure 118. The portion of the gate electrode 132 that extends over the STI structure 118 may be regarded as a field plate, and may be referred to as such with respect to FIG. 1 and similar figures.

Dielectric sidewall spacers 134 cover sidewalls of the gate electrode 132. The dielectric sidewall spacers 134 may also be referred to herein as gate spacers or gate sidewall spacers 134.

Silicide layers 136 form ohmic electrical connections to the drain region 116, the source region 124, the back gate or body contact region 126 and the gate electrode 132. The silicide layers 136 may also be referred to as metal silicide layers 136. A pre-metal dielectric (PMD) layer 138 covers the structure, and contacts 140 extend vertically from the silicide layers 136 to interconnects 144 separated by portions of an inter-metal dielectric (IMD) layer 142.

A method of forming the microelectronic device 100 including the LDMOS transistor 102 will now be described. As noted above, the LDMOS transistor 102 is shown as being n-channel. An analogous p-channel LDMOS transistor can be formed by substituting n-toped regions with p-doped regions and vice versa. In the case of an n-channel LDMOS transistor, a p-type region may be described as having a “first conductivity type” and an n-type region may be described as having a “second conductivity type.” Likewise, in the case of a p-channel LDMOS transistor, an n-type region may be described as having a first conductivity type and a p-type region may be described as having a second conductivity type.

The microelectronic device 100 includes a substrate including the epitaxial layer 104. The epitaxial layer 104 may, for example, by formed over a bulk semiconductor wafer, a silicon-on-insulator (SOI) wafer, or other structure suitable. A base wafer may be p-type with a dopant concentration of about 10¹⁷ atoms/cm³ to 10¹⁸ atoms/cm³. Alternatively, the base wafer may be lightly doped, meaning the base wafer has an average dopant concentration below 10¹⁶ atoms/cm³.

The optional NBL 108 is formed within the epitaxial layer 104. The NBL 108 may be about 2 micrometers (μm) to 10 μm thick, and may have a dopant concentration of about 10¹⁷ atoms/cm³ to 10¹⁸ atoms/cm³. The lightly doped region 112 (prior to formation of the PBL 110 as discussed below) extends from the NBL 108 to the top surface 105 of the epitaxial layer 104. The lightly doped region 112 may be about 2 μm to 12 μm thick. The lightly doped region 112 is p-type in the example in which the LDMOS transistor 102 is an n-channel device, and may have a dopant concentration of about 10¹⁵ atoms/cm³ to 10¹⁶ atoms/cm³. In versions where the optional NBL 108 is omitted, the unmodified portion 106 of the epitaxial layer is an extension of the lightly doped region 112.

A pad oxide layer (not specifically shown) of SiO₂ may be formed on the lightly doped region 112. The pad oxide layer may include SiO₂ that is formed by a thermal oxidation process or a CVD process. The pad oxide layer may provide stress relief between the lightly doped region 112 and subsequent layers. The pad oxide layer may be about 5 nanometers (nm) to 50 nm thick. A chemical mechanical planarization (CMP) stop layer may then be deposited, followed by formation of a mask layer. The CMP stop layer may be SiN or another material with a high selectivity for CMP of oxide materials. The mask layer serves the function of masking the CMP stop layer, and may be formed of a photoresist material and thus referred to as a photomask. The photomask may include a light sensitive organic material that is coated, exposed and developed. After formation and patterning of the mask layer, a plasma etch process is used to remove the CMP stop layer, the pad oxide layer and a portion of the lightly doped region 112 to form a field isolation trench. The field isolation trench may be about 250 nm to 1000 nm in depth.

The STI structure 118 is formed in the field isolation trench and over the CMP stop layer. The STI structure 118, as noted above, may include primarily SiO₂ or a SiO₂-based dielectric material that is formed by one or more CMP processes alternated with etch-back processes to provide complete filling of the field isolation trench. The STI structure 118 is planarized so that it does not extend over the top surface 105 of the epitaxial layer 104. After the STI structure 118 is planarized, the CMP stop layer is removed. The CMP stop layer may be removed by a wet etch process using an aqueous solution of phosphoric acid at about 140° C. to 170° C. The pad oxide layer may optionally be removed by a wet etch process using an aqueous solution of buffered hydrofluoric acid. The STI structure 118 forms a field oxide stress relief region for the LDMOS transistor 102.

A mask layer is then deposited and patterned in a region where a drift region implant is used to form the NDRIFT region 114 within exposed areas of the lightly doped region 112. The drift region implant may implant an n-type dopant in one or more steps. In some examples, phosphorus is implanted by multiple steps (e.g., a chain implant) resulting in a total dose of between about 3×10¹² cm⁻² and 6.6×10¹² cm⁻² with energies between about 0.5 mega-electron volts (MeV) and 2.8 MeV. In some examples arsenic is also implanted at an energy of between about 180 kilo-electron volts (keV) to 460 keV with a dose of between about 1.5×10¹² cm⁻² and 3.0×10¹² cm⁻². All of the implant processes may use the same mask layer to complete the formation of the NDRIFT region 114.

The PBL 110 may then be formed if used, for example, using a high energy p-type implant (a PBL implant) to add doping to the lightly doped region 112. The PBL implant can comprise boron at a dose from about 3×10¹² cm⁻² to 5×10¹² cm⁻² at an energy of between about 1.7 MeV and 3 MeV. Indium may also be used as the implant species. For low voltage (e.g., 20 V) versions of the LDMOS transistor 102, the PBL implant can be a blanket implant, while for higher voltage (e.g., >30 V) versions of the LDMOS transistor 102, the PBL implant may be a masked implant to allow selective placement.

After the wafer is cleaned, an implant mask is formed over the microelectronic device to expose an area where the p-type DWELL region 120 is to be formed. A DWELL implant process implants p-type dopants into a portion of the lightly doped region 112 laterally adjacent to the NDRIFT region 114, including at least a first well ion implant comprising a p-type dopant to form the p-type DWELL region 120. The p-type dopants implanted by the DWELL implant process may include boron. Besides boron, the p-type dopants can include indium. Indium, being a relatively large atom, has the advantage of a low diffusion coefficient relative to boron. In the case of a boron implant, the DWELL implant process can be similar in energy to energies used to form n-type source/drain regions or n-type lightly doped drain regions in the epitaxial layer 104, and the dose used should generally be sufficient to enable formation of a channel laterally and to suppress body NPN effects during operation of the LDMOS transistor 102. For example, a series of boron implants with an energy between about 80 keV and 3 MeV, and doses between about 4.0×10¹² cm⁻² to 1.5×10¹⁴ cm⁻², with a tilt angle of less than 10 degrees may be used to implant the p-type DWELL region 120. A rapid thermal process (RTP) may be used to activate dopants in the p-type DWELL region 120.

The field plate spacer 128 may be formed by depositing an insulating material over the wafer, followed by patterning of a mask layer over the insulating material in an area where the field plate spacer 128 is to be formed. This area is over at least a portion of the STI structure 118. Portions of the insulating material exposed by the mask layer are then removed using a suitable etch process, and the mask layer is removed.

The gate dielectric layer 130 is then formed by an oxidation process that may be implemented by a high temperature furnace operation or a rapid thermal process. The thickness of the gate dielectric layer 130 can range from about 3 nm to 15 nm if an SiO₂ dielectric is used, or thinner if a SiON dielectric with an electrically equivalent thickness is used. Optionally the gate dielectric layer 130 may be formed before the field plate spacer 128.

The gate electrode 132 is then formed over the gate dielectric layer 130, the STI structure 118 and the field plate spacer 128 using any suitable process. In some examples, the gate electrode 132 is polysilicon and may be deposited by a gate deposition process that may use a silane-based reagent. In other examples, the gate electrode 132 may be formed by a metal gate or CMOS-based replacement gate electrode process.

A mask layer is then deposited and patterned over the gate electrode 132. A plasma etch process defines the gate electrode 132, removing portions of the gate electrode 132 to avoid silicon surface damage during the etching process. The gate dielectric layer 130 extends from the STI structure 118 and over the p-type DWELL region 120.

A pattern and implant step using an n-type dopant such as arsenic or antimony may be used to form the n-type source extension region 122. In some examples, arsenic with a dose between about 6.0×10¹³ cm⁻² and 8.0×10¹⁵ cm⁻² with an energy between about 60 keV to 120 keV with a tilt angle of between 0 degrees and 45 degrees may be used for the n-type source extension region 122 dopant. An arsenic energy of greater than 15 keV can allow the arsenic to penetrate through the gate dielectric layer 130 (e.g., when a 5 V oxide is used for gate dielectric) adjacent to the gate electrode 132, which makes a lighter doped region under the future sidewall spacer to make a good connection between the source/drain and the inverted channel in the device for improved hot carrier performance. The arsenic implant may be implanted at an angle, thereby reducing the channel voltage threshold (Vt) without reducing the p-type DWELL region 120 implant dose, enabling the simultaneous improvement of Vt and control of the body doping of the parasitic NPN. Additionally, the arsenic dose may be made in more than one step to put most of the arsenic dose in the vertical implant and the rest into the angled implant.

After formation of the n-type source extension region 122, the dielectric sidewall spacers 134 are formed on sidewalls of the gate electrode 132. The dielectric sidewall spacers 134 may be formed by forming one or more conformal layers of dielectric material over the top surface 105 of the epitaxial layer 104 and the gate electrode 132. The dielectric material is subsequently removed from horizontal surfaces, that is, surfaces generally parallel to the top surface 105 of the epitaxial layer 104, by an anisotropic etch process such as an RIE process, leaving the dielectric material on the lateral surfaces of the gate electrode 132. The dielectric sidewall spacers 134 may include one or more dielectric materials such as SiO₂, SiN, etc. The dielectric sidewall spacers 134 may extend about 100 nm to 500 nm from the lateral surfaces of the gate electrode 132.

The drain region 116, the source region 124 and the back gate or body contact region 126 are then formed. One or more patterning and ion implantation steps are used to implant the drain region 116 in the NDRIFT region 114, and to implant the source region 124 and the back gate or body contact region 126 in the p-type DWELL region 120. The drain region 116 and the source region 124 implantation may occur in one or more steps with implant species including one or more of phosphorus and arsenic with an overall dose of between about 5×10¹³ cm⁻² and 4.5×10¹⁵ cm⁻² and an energy between about 2 keV and 80 keV. The drain region 116 contains an average dopant density many times higher than that of the NDRIFT region 114.

A silicide block layer may be formed by depositing one or more sublayers of an oxide material, a nitride material, an oxynitride material or any combination thereof over the top surface 105 of the epitaxial layer 104. The silicide block layer is then patterned using a mask layer and removed using a RIE etch process in regions where the silicide layers 136 are to be formed. The silicide block layer is allowed to remain in areas where the silicide layers 136 are not intended to be formed. In some examples, the silicide block layer is not required and may be omitted. A metal layer which forms a metal silicide at temperatures consistent with typical semiconductor manufacturing process conditions is then deposited on the wafer surface, and the microelectronic device 100 is heated to form the silicide layers 136 in exposed areas of the lightly doped region 112 and the gate electrode 132. Unreacted metal is subsequently removed in a wet stripping process.

After the silicide layers 136 are formed, the PMD layer 138 is formed. The PMD layer 138 may include a PMD liner (not specifically shown) over the microelectronic device 100. The PMD liner may be formed of a SiN, SiON, SiO₂, etc. The main dielectric sublayer of the PMD layer 138 is formed over the PMD liner, if present. The main dielectric sublayer of the PMD layer 138 may be formed by one or more dielectric deposition processes, including a PECVD process using TEOS, a high-density plasma (HDP) process, or a high aspect ratio process (HARP) using TEOS and ozone. The PMD layer 138 may be planarized by an oxide CMP process.

The contacts 140 may be formed by patterning and etching holes through the PMD layer 138 (and the PMD liner, if present) to expose portions of the silicide layers 136. The contacts 140 are filled in such holes, in some examples, by sputtering titanium or another suitable material to form a metal adhesion layer, followed by forming a titanium nitride (TiN) or other suitable diffusion barrier using reactive sputtering or an ALD process. A tungsten core may then be formed by an MOCVD process using tungsten hexafluoride (WF₆) reduced by silane initially and hydrogen after a layer of tungsten is formed on the TiN diffusion barrier. The tungsten, TiN, and titanium are subsequently removed from a top surface of the PMD layer 138 by a plasma etch process, a tungsten CMP process, or a combination of both, leaving the contacts 140 extending to the top surface of the PMD layer 138. In some examples, the contacts 140 may be formed by a selective tungsten deposition process which fills the contacts 140 with tungsten from the bottom up, forming the contacts 140 with a uniform composition of tungsten.

The interconnects 144 are then formed on the contacts 140. In some examples, the interconnects 144 have an etched aluminum structure, and may be formed by depositing an adhesion layer, an aluminum layer and an anti-reflection layer, and forming an etch mask followed by an RIE process to etch the anti-reflection layer, the aluminum layer and the adhesion layer where exposed by the etch mask, and subsequently removing the etch mask. In other examples, the interconnects 144 have a damascene structure, and may be formed by forming the IMD layer 142 on the PMD layer 138 and etching interconnect trenches through the IMD layer 142 to expose the contacts 140. A barrier liner (not shown) may be formed by sputtering tantalum onto the IMD layer 142, the PMD layer 138 and the contacts 140 which are exposed, and then forming tantalum nitride (TaN) on the sputtered tantalum by an ALD process. A copper fill metal may be formed by sputtering a seed layer (not shown) of copper on the barrier line, and electroplating copper on the seed layer to fill the interconnect trenches. The copper and barrier liner metal are subsequently removed from a top surface of the IMD layer 142 by a copper CMP process. In other examples, the interconnects 144 have a plated structure, and may be formed by sputtering an adhesion layer, containing titanium, on the PMD layer 138 and the contacts 140, followed by sputtering a seed layer of copper on the adhesion layer. A plating mask is formed on the seed layer that exposes areas for the interconnects 144. The interconnects 144 are then formed by electroplating copper on the seed layer where exposed by the plating mask. The plating mask is removed, and the seed layer and the adhesion layer are removed by wet etching between the interconnects 144.

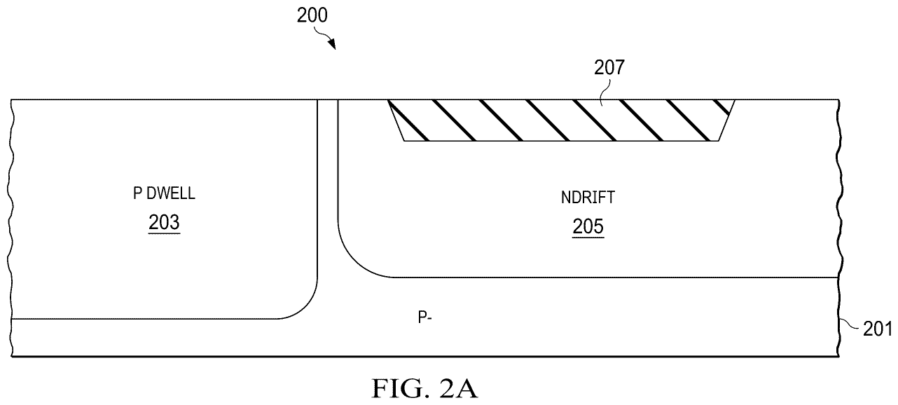

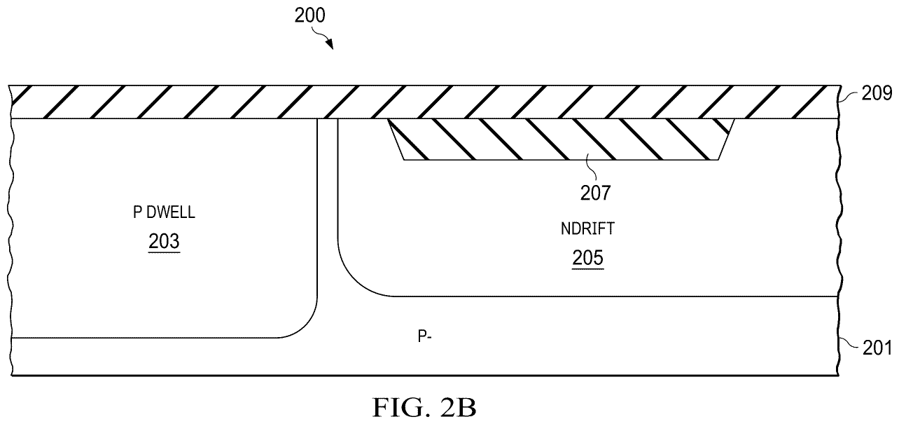

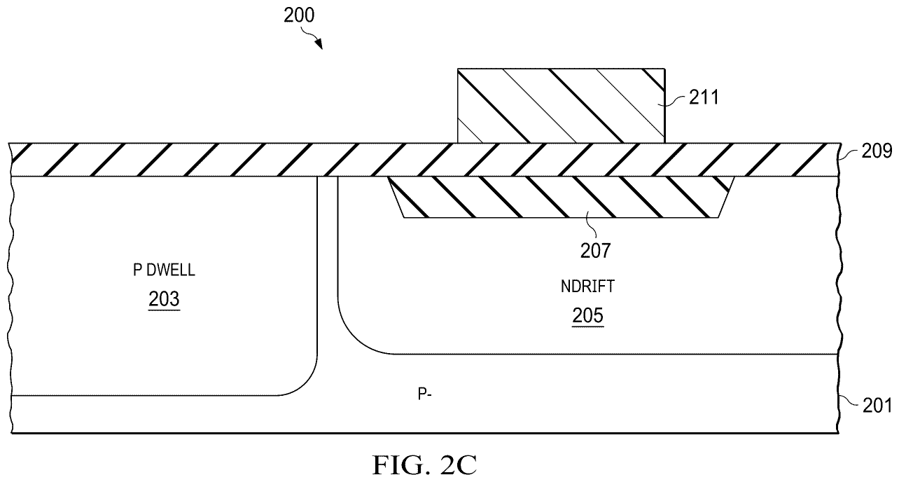

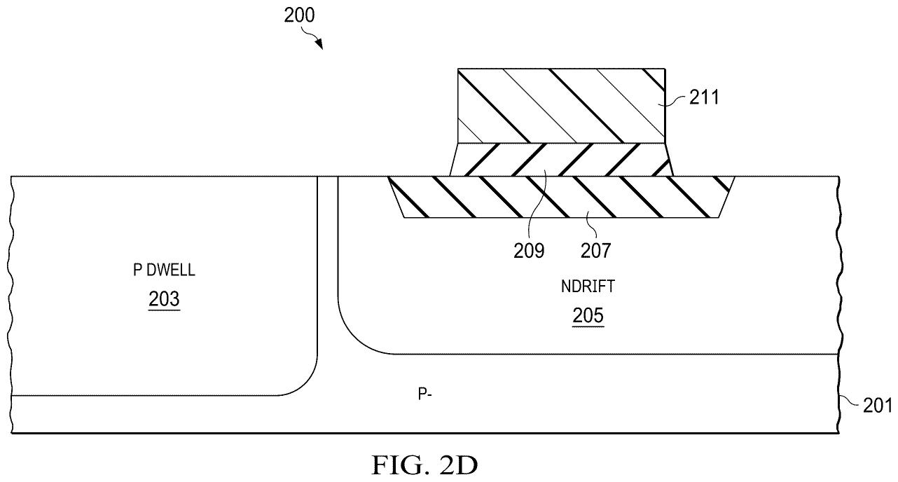

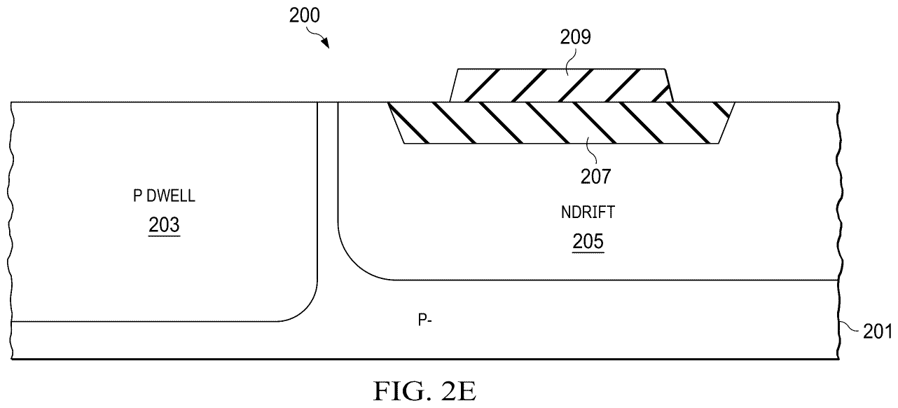

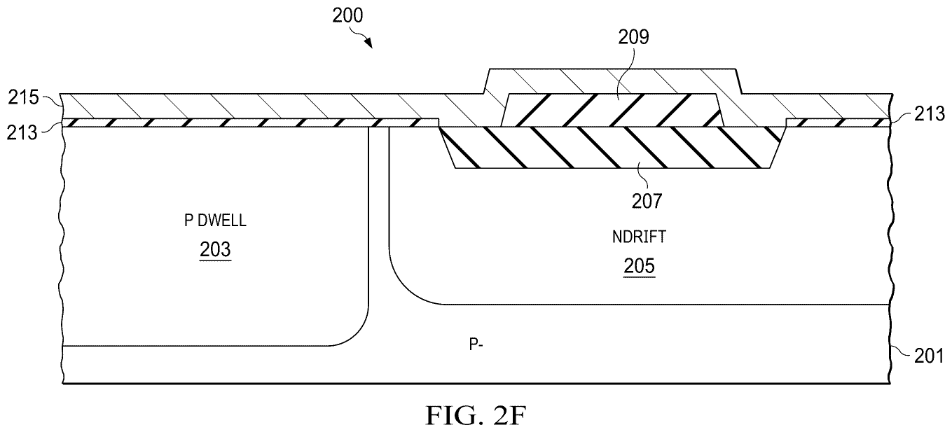

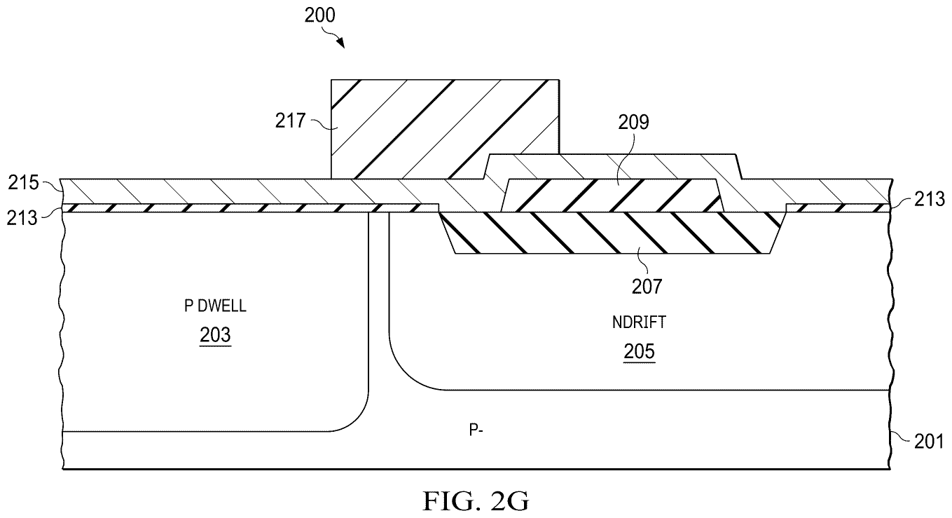

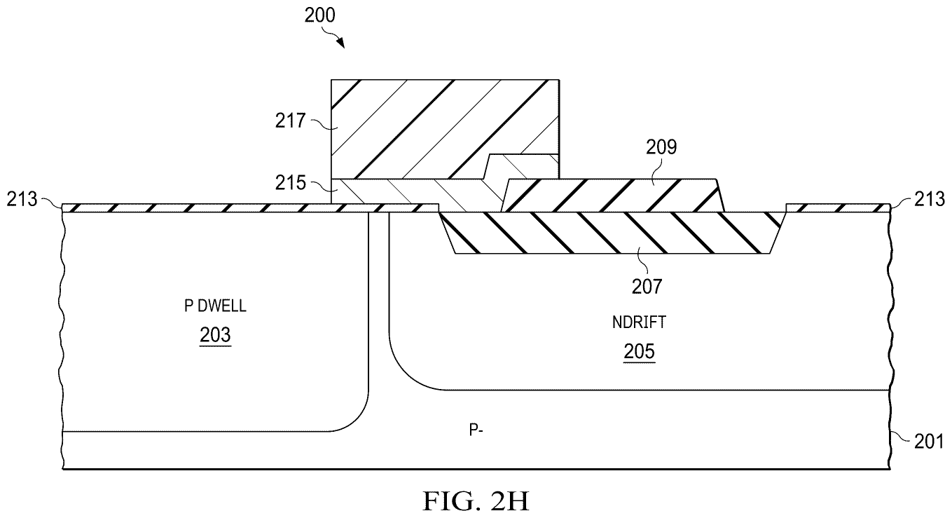

Referring now to FIGS. 2A-2H, cross-sectional views of a process flow for forming an insulating layer (e.g., field plate spacer 128) between a gate electrode (e.g., gate electrode 132) and an STI structure (e.g., STI structure 118) in a microelectronic device 200 are shown.

FIG. 2A shows the microelectronic device 200 including a lightly doped p-type epitaxial layer 201, which may be formed over a substrate and optional NBL/PBL layers (not shown) similar to the lightly doped region 112 of the microelectronic device 100 shown in FIG. 1. A p-type DWELL region 203 and NDRIFT region 205 are formed within the lightly doped p-type epitaxial layer 201. An STI structure 207 has been formed within the NDRIFT region 205. The p-type DWELL region 203, the NDRIFT region 205 and the STI structure 207 may be formed using processing similar to that described above with respect to formation of the p-type DWELL region 120, the NDRIFT region 114 and the STI structure 118, respectively.

FIG. 2B shows the microelectronic device 200 of FIG. 2A following formation of a field plate spacer 209. The field plate spacer 209 may be a nitride material, or at least a different dielectric material than the STI structure 207 and may have a dielectric constant k≥4. In some examples, the STI structure 207 is SiO₂-based and the field plate spacer 209 is SiN-based. Before the deposition of the field plate spacer 209 on top of the silicon surface of the lightly doped p-type epitaxial layer 201, a sacrificial oxide layer (not shown) may be deposited which can protect the substrate surface from plasma damage resulting from etching of the field plate spacer 209. This sacrificial oxide layer will be removed before the gate oxide is formed.

FIG. 2C shows the microelectronic device 200 of FIG. 2B following patterning of a mask layer 211 over the field plate spacer 209. The mask layer 211 is patterned over a portion of the field plate spacer 209 that is formed over the STI structure 207.

FIG. 2D shows the microelectronic device 200 of FIG. 2C following removal of portions of the field plate spacer 209 exposed by the mask layer 211. This may utilize any suitable etch processing which is able to remove the material of the field plate spacer 209 selective to the material of the STI structure 207 and the lightly doped p-type epitaxial layer 201. As shown in FIG. 2D, the etching of the field plate spacer 209 results in the remaining portion of the field plate spacer 209 having tapered sidewalls, though this is not a requirement.

FIG. 2E shows the microelectronic device 200 of FIG. 2D following removal of the mask layer 211.

FIG. 2F shows the microelectronic device 200 of FIG. 2E following formation of a gate dielectric layer 213 and a gate electrode layer 215. The gate dielectric layer 213 and the gate electrode layer 215 may be formed using processing similar to that described above with respect to the gate dielectric layer 130 and the gate electrode 132.

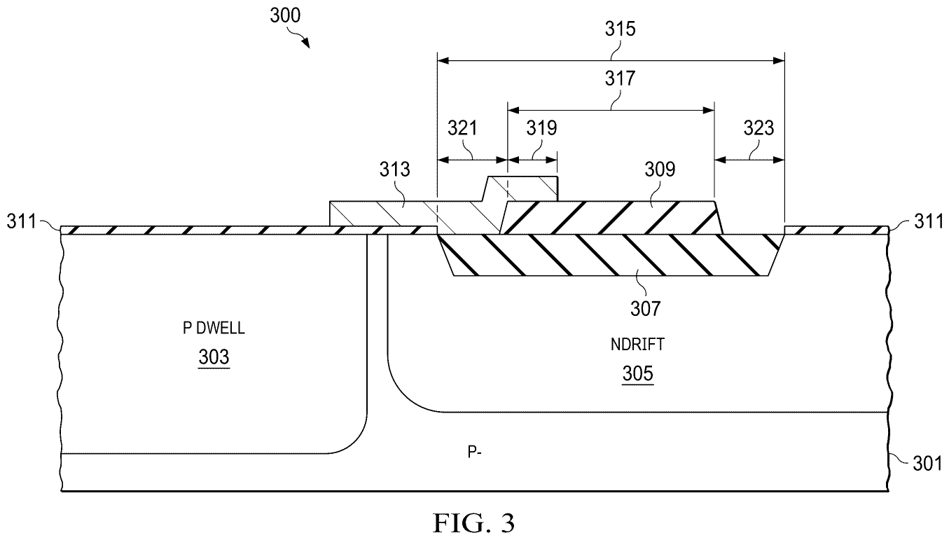

FIG. 2G shows the microelectronic device 200 of FIG. 2F following patterning of a mask layer 217 over the gate electrode layer 215. The mask layer 217 may be patterned to control how much of the field plate spacer 209 will be covered by the gate electrode layer 215. Various examples for tuning such cover or overlap will be described in further detail below with respect to FIGS. 3-5.

FIG. 2H shows the microelectronic device 200 of FIG. 2G following removal of portions of the gate electrode layer 215 exposed by the mask layer 217. The structure of FIG. 2H may be subject to further processing for forming other parts of a drain-extended transistor device such as an LDMOS transistor, including removal of the mask layer 217 and subsequent formation of source and drain regions, gate sidewall spacers, silicide layers, a PMD layer, contacts, and IMD layer and interconnects using processing similar to that described above with respect to formation of similar parts of the LDMOS transistor 102.

Referring now to FIG. 3, a microelectronic device 300 is shown, including a p-type lightly doped epitaxial layer 301, a p-type DWELL region 303, an NDRIFT region 305, an STI structure 307, a field plate spacer 309, a gate dielectric layer 311 and a gate electrode 313. These features are analogous to those shown in the microelectronic device 100. FIG. 3 illustrates various dimensions, including a width 315 of the STI structure 307, a width 317 of the field plate spacer 309, a width 319 of a portion of the gate electrode 313 that extends over the field plate spacer 309, a distance 321 from the source-side edge of the STI structure 307 to the beginning or source-side edge of the field plate spacer 309, and a distance 323 from an end of the field plate spacer 309 to a drain-side edge of the STI structure 307. The width 315 may be in the range of about 0.5 μm to 3 μm, and the width 317 may be in the range of about 0.3 μm to 2.5 μm. The width 319 may vary in the range of about 0.2 μm to 2.3 μm. The width 319, in some examples, has a minimum overlap of 0.2 μm to ensure that the gate electrode 313 is always overlapping the field plate spacer 309, to account for the slope of the sidewalls of the field plate spacer 309 due to etching and to avoid misalignment. The distance 321 may be about 0.3 μm or more, and the distance 323 may be about 0.3 μm or more. Increasing the width of the field plate spacer 309 to cover all, or greater than 90%, of the underlying STI structure 307 is expected to effectively mitigate the effect of any STI cone defects that may exist. STI cone defects, generally resulting from occasional and randomly placed particles blocking the field isolation trench etch, may occur anywhere in the STI structure 307. If there is a buffer of the field plate spacer 309, the device can be protected from the effects of STI cones and prevent device failure. On the drain side, the field plate spacer 309 may be extended generally to the lateral limit of the drain-side of the field plate spacer 309, without significantly impacting device performance, to protect from STI cone defects. On the source side, however, extending the field plate spacer 309 is expected to impact the device BV and Rdson.

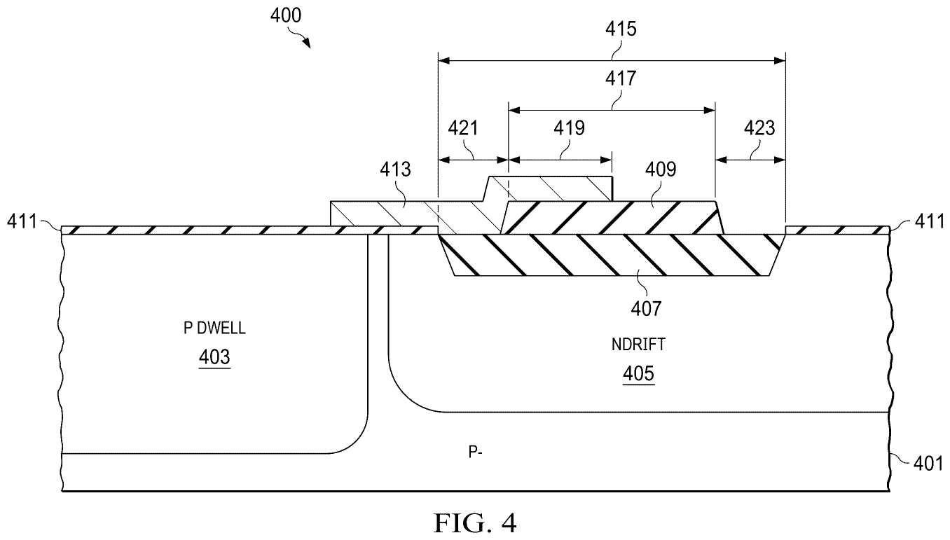

Referring now to FIG. 4, a microelectronic device 400 is shown, including a p-type lightly doped epitaxial layer 401, a p-type DWELL region 403, an NDRIFT region 405, an STI structure 407, a field plate spacer 409, a gate dielectric layer 411 and a gate electrode 413. These features are analogous to those shown in the microelectronic devices 100 and 300. FIG. 4 illustrates various dimensions, including a width 415 of the STI structure 407, a width 417 of the field plate spacer 409, a width 419 of a portion of the gate electrode 413 that extends over the field plate spacer 409, a distance 421 from the source-side edge of the STI structure 407 to the beginning or source-side edge of the field plate spacer 409, and a distance 423 from an end of the field plate spacer 409 to a drain-side edge of the STI structure 407. The widths 415 and 417 and distances 421 and 423 may be similar to those of the widths 315 and 317 and the distances 321 and 323. The width 419, however, is larger than the width 319. For example, the width 419 may be at least 40% of the width 417.

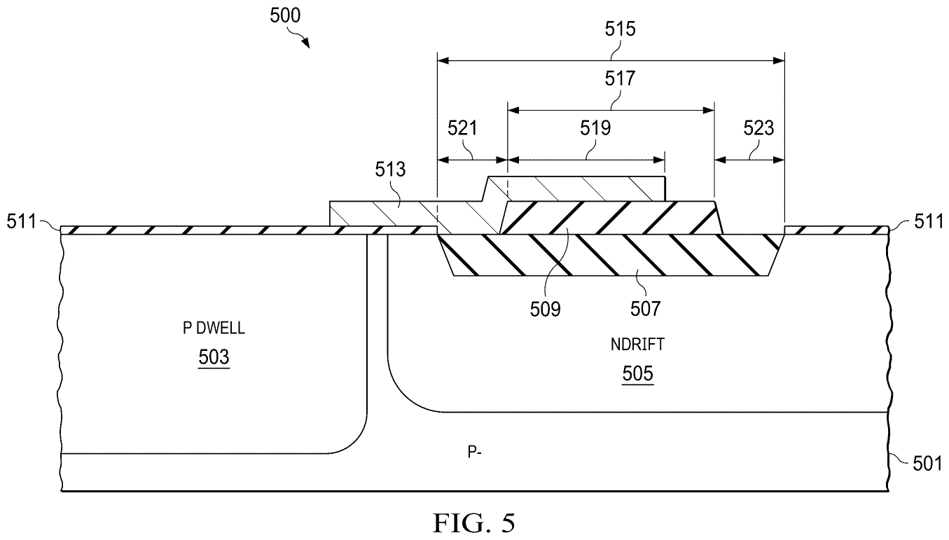

Referring now to FIG. 5, a microelectronic device 500 is shown, including a p-type lightly doped epitaxial layer 501, a p-type DWELL region 503, an NDRIFT region 505, an STI structure 507, a field plate spacer 509, a gate dielectric layer 511 and a gate electrode 513. These features are analogous to those shown in the microelectronic devices 100, 300 and 400. FIG. 5 illustrates various dimensions, including a width 515 of the STI structure 507, a width 517 of the field plate spacer 509, a width 519 of a portion of the gate electrode 513 that extends over the field plate spacer 509, a distance 521 from the source-side edge of the STI structure 507 to the beginning or source-side edge of the field plate spacer 509, and a distance 523 from an end of the field plate spacer 509 to a drain-side edge of the STI structure 507. The widths 515 and 517 and distances 521 and 523 may be similar to those of the widths 315, 415 and 317, 417 and the distances 321, 421 and 323, 423. The width 519, however, is larger than the widths 319 and 419. For example, the width 519 may be at least 90% of the width 517.

As illustrated in FIGS. 3-5, the extent of overlap (widths 319, 419, 519) of a gate electrode (gate electrode 313, 413, 513) over a field plate spacer (309, 409, 509) disposed over an STI structure (307, 407, 507) may be selected as desired for a particular application. In some examples, the amount that the gate electrode extends over the field plate spacer is maximized to provide improvement in the BV and Rsp characteristics of an LDMOS or other transistor device. In some examples, the peak of the electric field may be reduced through selecting the widths 317 and 319 relative to a fixed width 315 of the STI structure 307, to achieve a best possible BV for a given device.

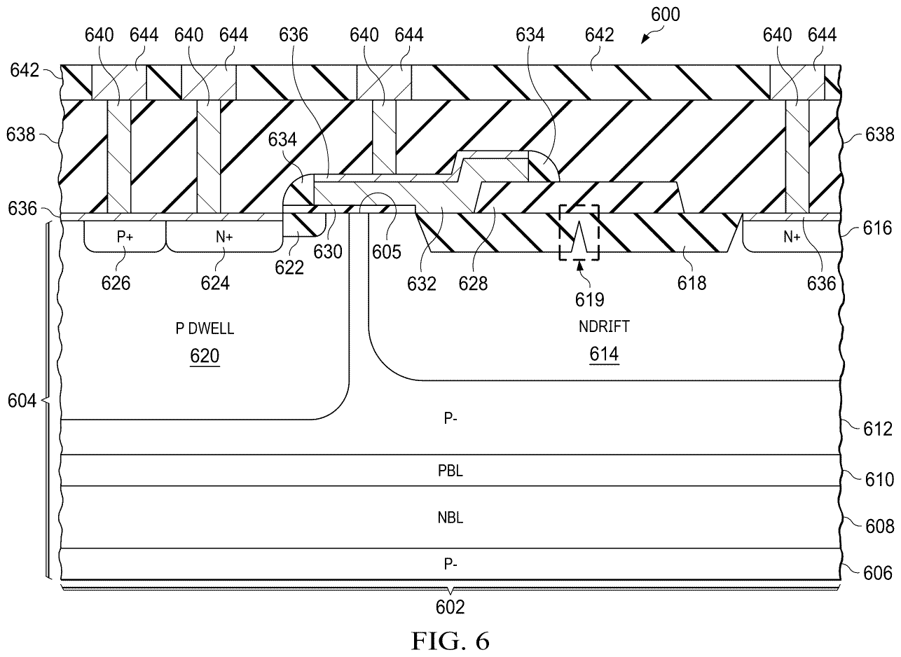

Referring now to FIG. 6, a microelectronic device 600 is shown including an LDMOS transistor 602, epitaxial layer 604 with top surface 605, optional NBL 608, optional PBL 610, an unmodified portion 612 of the epitaxial layer 604 (also referred to as lightly doped region 612), NDRIFT region 614, drain region 616, STI structure 618, p-type DWELL region 620, n-type source extension region 622, source region 624, back gate or body contact region 626, field plate spacer 628, gate dielectric layer 630, gate electrode 632, dielectric sidewall spacers 634, silicide layers 636, PMD layer 638, contacts 640, IMD layer 642 and interconnects 644. These features are analogous to those of the microelectronic device 100 of FIG. 1. FIG. 6 further illustrates a cone defect 619 that is present in the STI structure 618. The cone defect 619 negatively impacts the isolation performance of the STI structure 618. Advantageously, the field plate spacer 628 disposed over the STI structure 618 can mitigate the negative impact of the cone defect 619 on the isolation performance of the STI structure 618 by increasing the STI cone to polysilicon (gate electrode 632) breakdown. The field plate spacer 628 can reduce the electric field peak which would otherwise result from having the cone defect in the STI structure 618 directly against the gate electrode 632. The field plate spacer 628 disposed between at least a portion of the gate electrode 632 and the underlying STI structure 618 can provide at least an order of magnitude (10×) reduction in the absolute electric field at the tip (e.g., a top surface) of the cone defect 619.

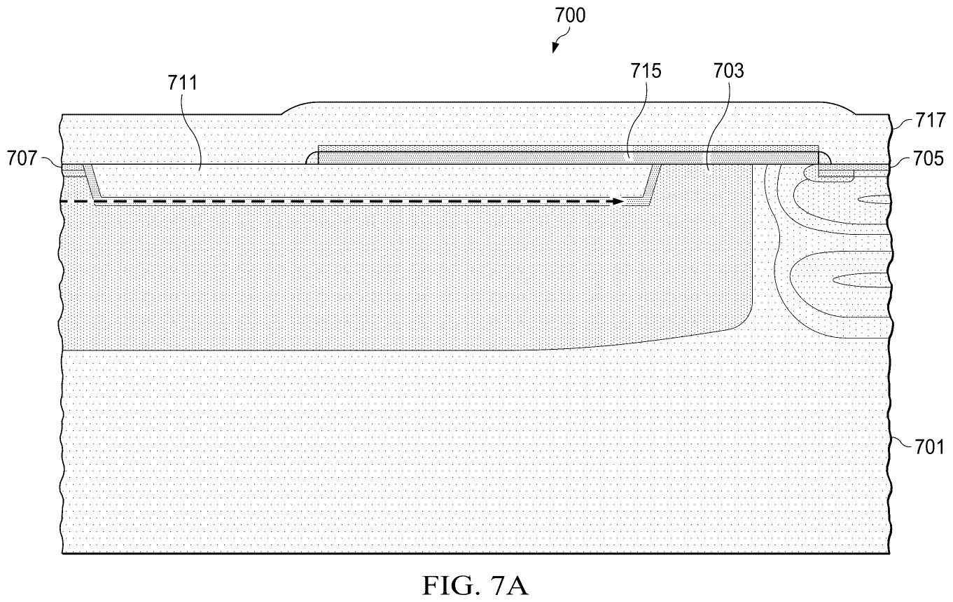

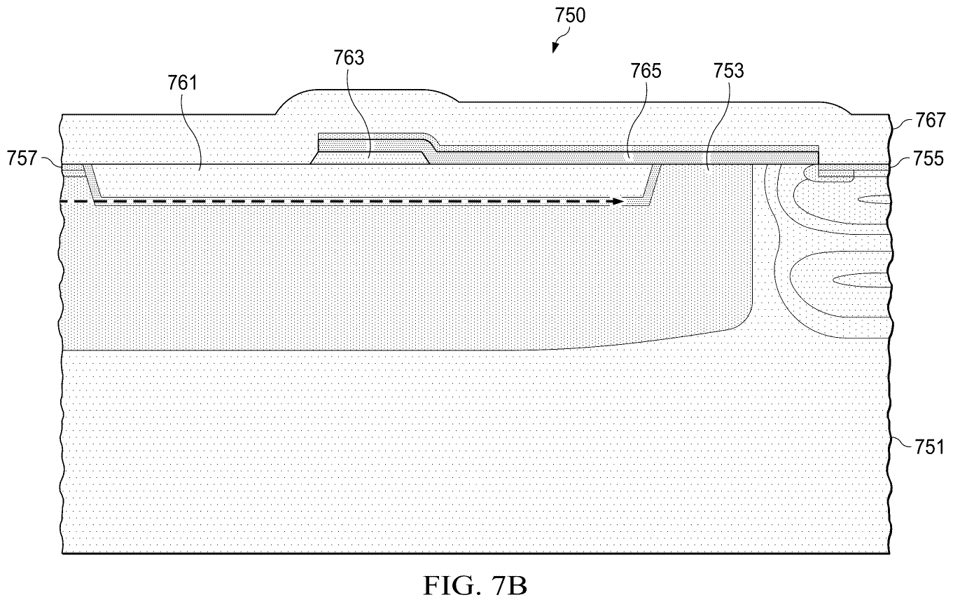

Referring now to FIGS. 7A and 7B, modelled portions of microelectronic devices 700 and 750 are shown. The microelectronic device 700 includes an epitaxial layer 701 (analogous to the lightly doped region 112 in the microelectronic device 100), a drain drift region 703, a source region 705, a drain region 707, an STI structure 711, a gate electrode/field plate 715 and an oxide layer 717. The microelectronic device 750 includes an epitaxial layer 751 (analogous to the lightly doped region 112 in the microelectronic device 100), a drain drift region 753, a source region 755, a drain region 757, an STI structure 761, a field plate spacer 763, a gate electrode/field plate 765, and an oxide layer 767. In each of FIGS. 7A and 7B the horizontal axis is a measure of distance from the drain region toward the source region. Without implied limitation the STI structures 711, 761 were modelled as having a dielectric constant k=3.9 consistent with silicon oxide, and the field plate spacer 763 was modelled as having a dielectric constant k=7.9 consistent with silicon nitride.

The field plate spacer 763 is disposed between the field plate portion of the gate electrode 765 and the STI structure 761. The field plate spacer 763 is modelled as having a dielectric constant k=7.9 without implied limitation. The field plate spacer 763 may be a nitride material, the STI structure 755 may be an oxide material, and the gate electrode 759 may be a polysilicon material. The field plate spacer 763 results in a stepped-polysilicon nitride field plate An insulating layer analogous to the field plate spacer 763 is omitted from the microelectronic device 700 to provide a comparison of electric fields between the two devices.,

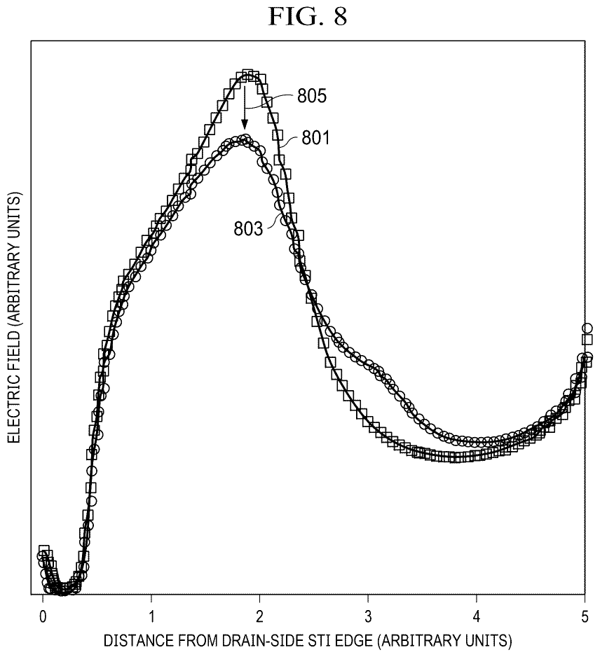

FIG. 8 presents modelled electric field plots 801 and 803 respectively corresponding to the devices 700 and 750. These plots show the computed electric field in arbitrary units at the substrate surface as a function of a lateral distance from the drain toward the source. Both plots have a local maximum near the drain-side end of the respective field plate portion of gate electrode/field plates 715, 765, at about 2 units on the horizontal axis. A difference 805 between the maximum of the plot 801, corresponding to absence of the field plate spacer, and the plot 803, corresponding to the presence of the field plate spacer, represents about a 15% reduction of the electric field strength at this location of the modelled device 750. This reduction advantageously improves the breakdown voltage of the microelectronic device 750 relative to the microelectronic device 700. This improvement is expected to increase reliability of devices including a field plate spacer consistent with the present disclosure, and/or provide flexibility to allow other design parameters to improve such devices, such as reduction of Rsp.

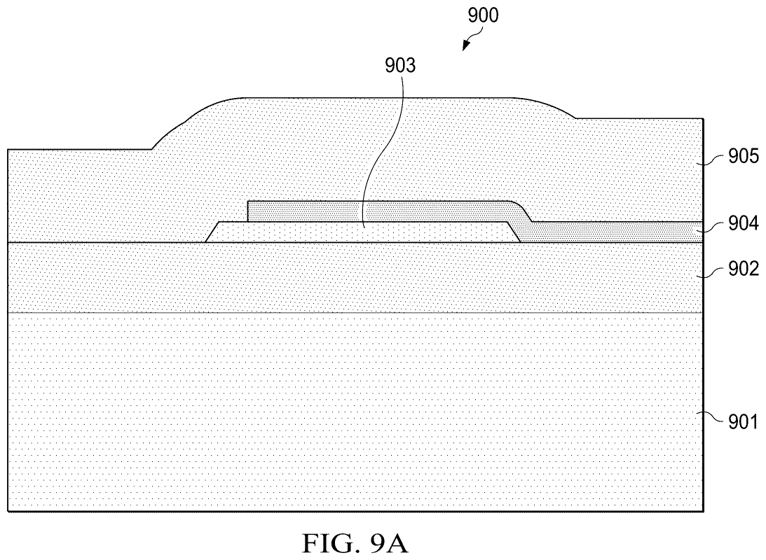

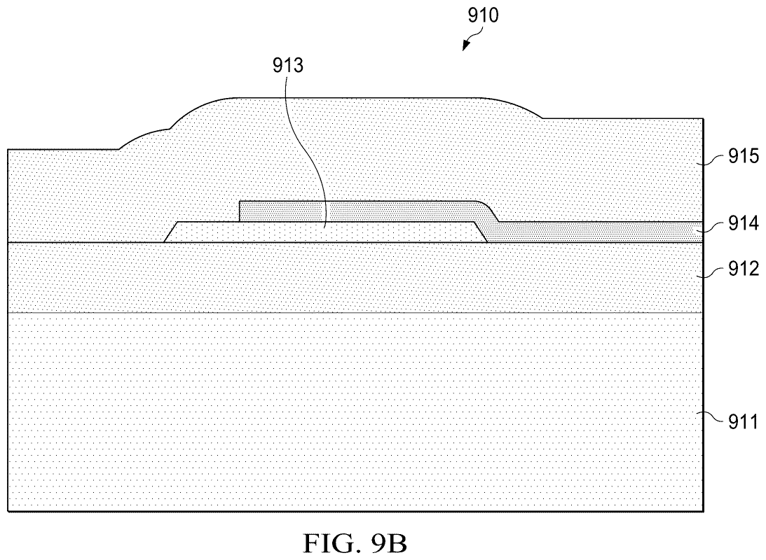

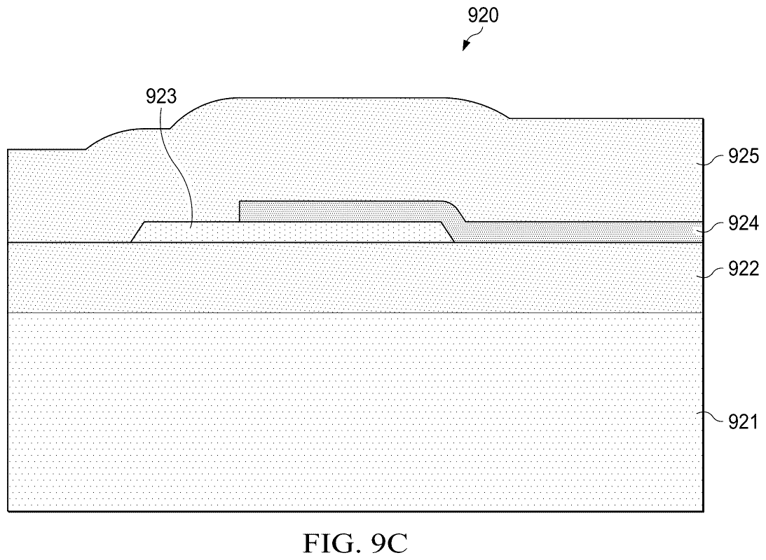

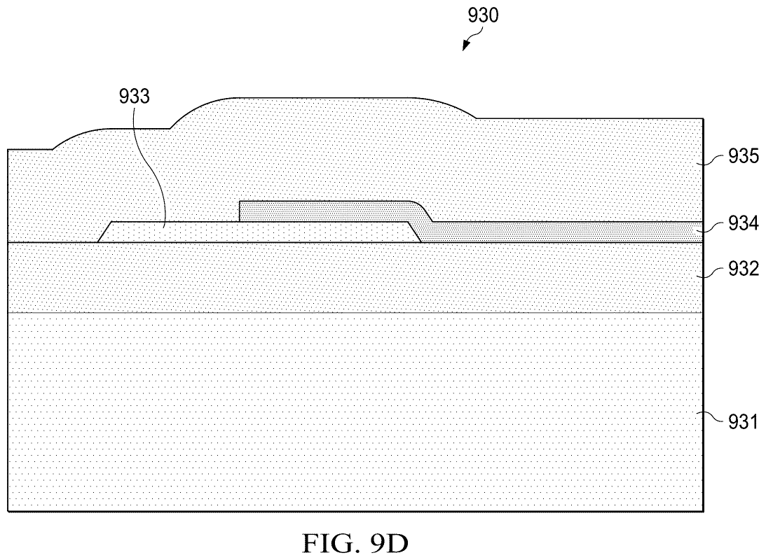

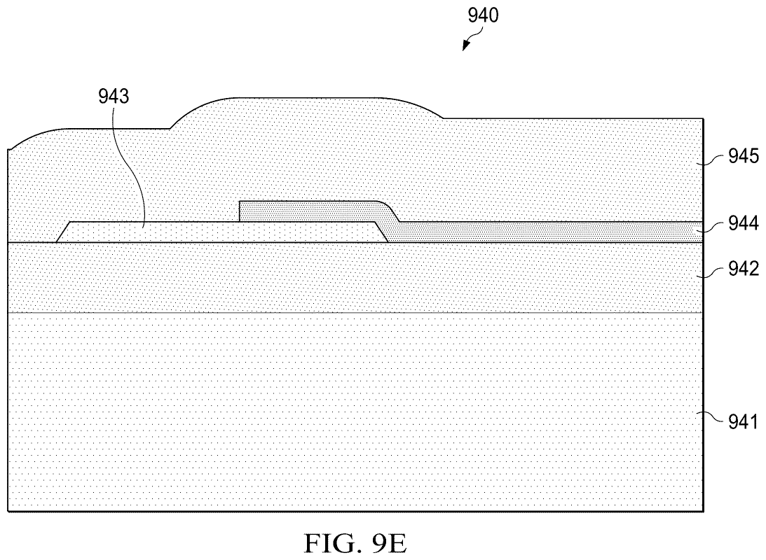

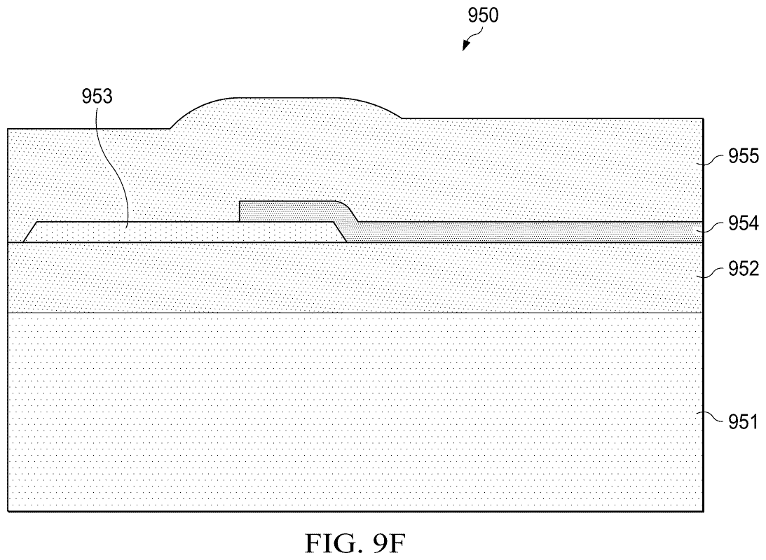

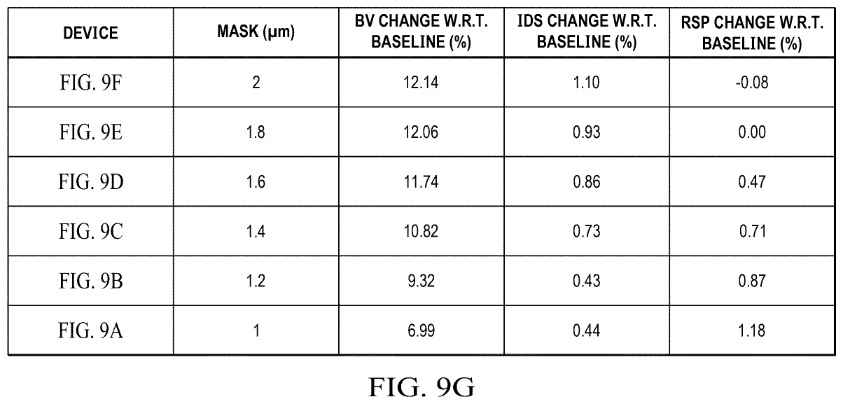

Referring now to FIGS. 9A-9F, modelled portions of microelectronic devices 900, 910, 920, 930, 940 and 950 are shown.

FIG. 9A shows the microelectronic device 900, including an epitaxial layer 901 (analogous to the lightly doped region 112 in the microelectronic device 100), an STI structure 902, a field plate spacer 903, a gate electrode 904, and an oxide layer 905. The field plate spacer 903 is disposed between a field plate portion of the gate electrode 904 and the STI structure 902.

FIG. 9B shows the microelectronic device 910, including an epitaxial layer 911 (analogous to the lightly doped region 112 in the microelectronic device 100), an STI structure 912, a field plate spacer 913, a gate electrode 914, and an oxide layer 915. The field plate spacer 913 is disposed between a field plate portion of the gate electrode 914 and the STI structure 912.

FIG. 9C shows the microelectronic device 920, including an epitaxial layer 921 (analogous to the lightly doped region 112 in the microelectronic device 100), an STI structure 922, a field plate spacer 923, a gate electrode 924, and an oxide layer 925. The field plate spacer 923 is disposed between a field plate portion of the gate electrode 924 and the STI structure 922.

FIG. 9D shows the microelectronic device 930, including an epitaxial layer 931 (analogous to the lightly doped region 112 in the microelectronic device 100), an STI structure 932, a field plate spacer 933, a gate electrode 934, and an oxide layer 935. The field plate spacer 933 is disposed between a field plate portion of the gate electrode 934 and the STI structure 932.

FIG. 9E shows the microelectronic device 940, including an epitaxial layer 941 (analogous to the lightly doped region 112 in the microelectronic device 100), an STI structure 942, a field plate spacer 943, a gate electrode 944, and an oxide layer 945. The field plate spacer 943 is disposed between a field plate portion of the gate electrode 944 and the STI structure 942.

FIG. 9F shows the microelectronic device 950, including an epitaxial layer 951 (analogous to the lightly doped region 112 in the microelectronic device 100), an STI structure 952, a field plate spacer 953, a gate electrode 954, and an oxide layer 955. The field plate spacer 953 is disposed between a field plate portion of the gate electrode 954 and the STI structure 952.

In FIGS. 9A-9F, the length and position of the gate electrodes 904, 914, 924, 934, 944 and 954 are kept the same as a baseline structure which does not include a field plate spacer. The width of the field plate spacer, however, is varied among the microelectronic structures 900, 910, 920, 930, 940 and 950, through varying a mask size used when forming the field plate spacers 903, 913, 923, 933, 943 and 953. FIG. 9G shows a table illustrating modeled values of the change in BV, drain-to-source current (Ids) and Rsp, with respect to the baseline structure. As illustrated in the table of FIG. 9G, the width of the field plate spacer, defined by the mask width, may be tuned to achieve a desired balance of BV, Ids and Rsp. The BV parameter, for example, exhibits a more than 10% improvement in BV for mask lengths of 1.4 μm or greater.

In addition, while in accordance with illustrated implementations, various features or components have been shown as having particular arrangements or configurations, other arrangements and configurations are possible. Moreover, aspects of the present technology described in the context of example implementations may be combined or eliminated in other implementations. Thus, the breadth and scope of the description is not limited by any of the above-described implementations.

What is claimed is:

1. A semiconductor device, comprising:
a source region and a drain region having a first conductivity type disposed in a semiconductor layer having an opposite second conductivity type;
a shallow trench isolation structure disposed in the semiconductor layer between the source region and the drain region;
a gate dielectric layer disposed over the semiconductor layer and extending between the source region and the shallow trench isolation structure;
a gate electrode disposed over the gate dielectric layer and extending toward the drain region and over the shallow trench isolation structure; and
a field plate spacer between the gate electrode and the shallow trench isolation structure.

2. The semiconductor device of claim 1, wherein the field plate spacer is a nitride material.

3. The semiconductor device of claim 1, wherein the shallow trench isolation structure comprises a first dielectric material and the field plate spacer comprises a different second dielectric material.

4. The semiconductor device of claim 3, wherein the first dielectric material is silicon oxide and the second dielectric material is silicon nitride.

5. The semiconductor device of claim 3, wherein second dielectric material has a greater dielectric permittivity than the first dielectric material.

6. The semiconductor device of claim 1, wherein the gate electrode covers more than 50% of the field plate spacer.

7. The semiconductor device of claim 1, wherein the gate electrode covers at least 40% of the field plate spacer.

8. The semiconductor device of claim 1, wherein the gate electrode covers at least 90% of the field plate spacer.

9. The semiconductor device of claim 1, wherein the first conductivity type is n-type and the second conductivity type is p-type.

10. The semiconductor device of claim 1, wherein the source region and the drain region are components of a laterally diffused metal oxide semiconductor (LDMOS) transistor.

11. A method of forming a semiconductor device, comprising:
forming a source region and a drain region having a first conductivity type in a semiconductor layer having an opposite second conductivity type;
forming a shallow trench isolation structure in the semiconductor layer between the source region and the drain region;
forming a gate dielectric layer over the semiconductor layer and extending between the source region and the shallow trench isolation structure;
forming a gate electrode over the gate dielectric layer and extending toward the drain region and over the shallow trench isolation structure; and
forming a field plate spacer between the gate electrode and the shallow trench isolation structure.

12. The method of claim 11, wherein the field plate spacer is a nitride material.

13. The method of claim 11, wherein the shallow trench isolation structure comprises a first dielectric material and the field plate spacer comprises a different second dielectric material.

14. The method of claim 13, wherein the first dielectric material is silicon oxide and the second dielectric material is silicon nitride.

15. The method of claim 13, wherein second dielectric material has a greater dielectric permittivity than the first dielectric material.

16. The method of claim 11, wherein the gate electrode covers more than 50% of the field plate spacer.

17. The method of claim 11, wherein the gate electrode covers at least 40% of the field plate spacer.

18. The method of claim 11, wherein the gate electrode covers at least 90% of the field plate spacer.

19. The method of claim 11, wherein the first conductivity type is n-type and the second conductivity type is p-type.

20. The method of claim 11, wherein the source region and the drain region are components of a laterally diffused metal oxide semiconductor (LDMOS) transistor.
